(19) United States
(12) Patent Application Publication
(10) Pub. No.: US 2011/0249415 A1
(43) Pub. Date: Oct. 13, 2011

(54) ELECTRONIC APPARATUS

(75) Inventor: Satoshi TAKEZAKI, Ome-shi (JP)

(73) Assignee: KABUSHIKI KAISHA TOSHIBA, Tokyo (JP)

(21) Appl. No.: 13/163,467

(22) Filed: Jun. 17, 2011

Related U.S. Application Data
(63) Continuation of application No. 12/704,009, filed on Feb. 11, 2010.

(30) Foreign Application Priority Data
May 29, 2009 (JP) 2009-131132

(51) Int. Cl. H05K 5/00

(52) U.S. Cl. 361/752

(57) ABSTRACT

According to one embodiment, an electronic apparatus includes a main unit with a housing having an upper wall, a front wall, a rear wall facing a communicating party, a display rotatably attached to the main unit, a circuit board in the housing of the main unit, a directional antenna on the circuit board, and a reflecting plate between the antenna and an inner surface of the housing. The antenna emits a radio wave in a direction substantially orthogonal to the upper wall. The reflecting plate reflects the radio wave from the antenna toward the rear wall in order to allow the radio wave to travel toward the communicating party through the rear wall. The electronic apparatus can be operated with the display screen and the communicating party in a same direction from the perspective of a position facing the front wall.

### CROSS-REFERENCE TO RELATED APPLICATIONS

This application is a continuation of U.S. patent application Ser. No. 12/704,009, filed Feb. 11, 2010, which is based upon and claims the benefit of priority from Japanese Patent Application No. 2009-131132, filed May 29, 2009, the entire contents of both of which are hereby incorporated by reference herein.

### BACKGROUND

1. Field

One embodiment of the invention relates to an electronic apparatus comprising an antenna.

2. Description of the Related Art

Electronic apparatuses, such as notebook computers, comprise various kinds of antennas. Jpn. Pat. Appln. KOKAI Publication No. 10-209908 discloses an information processing apparatus comprising a wireless module comprising an antenna. The wireless module comprises an IF circuit, an RF circuit, and an antenna. A movable connector is provided on a transmission path that connects the IF circuit and the RF circuit.

Jpn. Pat. Appln. KOKAI Publication No. 8-256006 discloses an antenna device comprising a parabolic antenna. The antenna device comprises a parabolic antenna in which the axis line of a paraboloidal surface is fixed in the vertical direction and a reflecting plate that is inclined at a predetermined angle with respect to the axis line of the paraboloidal surface of the parabolic antenna and can be rotated in the horizontal direction.

Some antennas have relatively high directivity. When a circuit board having the antenna mounted thereon is provided in a housing of an electronic apparatus, there are various limitations in the mounting position or posture of the circuit board due to high directivity of the antenna. Therefore, it is difficult to achieve a mounting structure suitable for the internal structure of the housing.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view illustrating an electronic apparatus according to a first embodiment of the invention;

FIG. 2 is an exemplary cross-sectional view illustrating the electronic apparatus shown in FIG. 1;

FIG. 3 is an exemplary cross-sectional view illustrating a modification of the electronic apparatus shown in FIG. 1;

FIG. 4 is an exemplary cross-sectional view illustrating an electronic apparatus according to a second embodiment of the invention;

FIG. 5 is an exemplary plan view illustrating the electronic apparatus shown in FIG. 4;

FIG. 6 is an exemplary perspective view illustrating a second reflecting plate shown in FIG. 4;

FIG. 7 is an exemplary perspective view illustrating the attachment structure of the second reflecting plate shown in FIG. 6; and

FIG. 8 is an exemplary cross-sectional view illustrating an electronic apparatus according to a third embodiment of the invention.

### DETAILED DESCRIPTION

Various embodiments according to the invention will be described hereinafter with reference to the accompanying drawings. In general, according to one embodiment of the invention, an electronic apparatus comprising: a housing; a circuit board in the housing, an antenna being on the circuit board; and a reflecting plate facing the antenna and configured to reflect a radio wave radiated from the antenna to change a direction of the radio wave.

Hereinafter, exemplary embodiments of the invention applied to a notebook computer will be described with reference to the accompanying drawings.

### First Embodiment

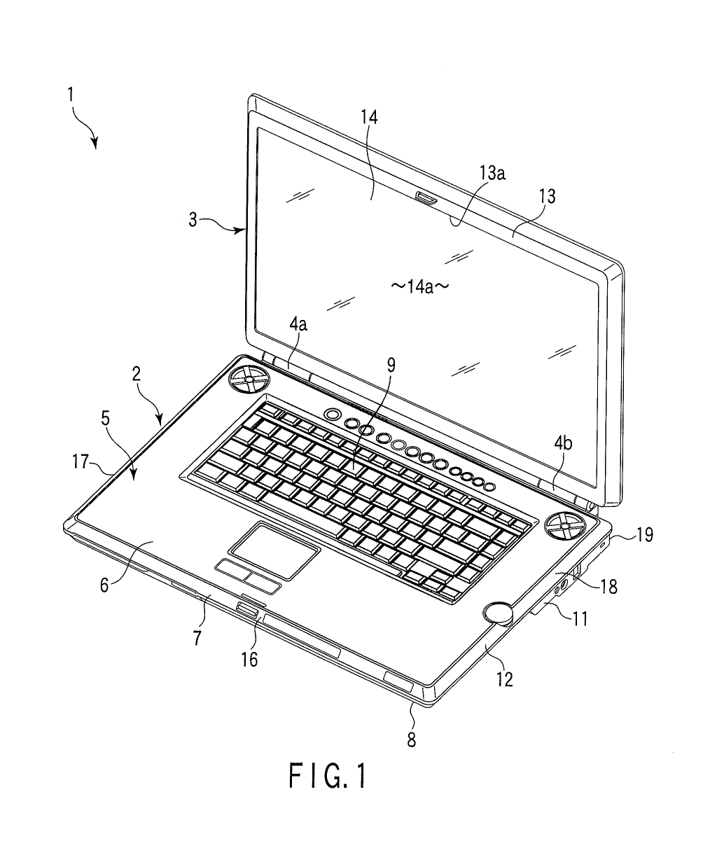

FIGS. 1 to 3 are diagrams illustrating an electronic apparatus 1 according to a first embodiment of the invention. The electronic apparatus 1 is, for example, a notebook personal computer. The electronic apparatus according to the invention is not limited thereto. The invention can be applied to various kinds of electronic apparatuses comprising, for example, various kinds of installation type information processing apparatuses, a display apparatus such as a television, a recording/reproducing apparatus such as a DVD player, and a game machine.

The electronic apparatus 1 comprises a main unit 2, a display unit 3, and hinge portions 4a and 4b. The main unit 2 is an electronic apparatus main body having a main circuit board. The main unit 2 comprises a flat box-shaped housing 5. The housing 5 comprises an upper wall 6, a peripheral wall 7, and a lower wall 8. The lower wall 8 faces a work surface when the electronic apparatus 1 is placed on the work surface (for example, a desk). The lower wall 8 extends so as to be substantially parallel to the work surface.

The upper wall 6 extends substantially in parallel to the lower wall 8 (that is, substantially horizontally) with a space therebetween. The upper wall 6 supports a keyboard 9 that is provided on the housing 5. The peripheral wall 7 is provided vertically to the lower wall 8 and connects the edge of the lower wall 8 and the edge of the upper wall 6.

The housing 5 comprises a housing base 11 including the lower wall 8 and a portion of the peripheral wall 7 and a housing cover 12 including the upper wall 6 and a portion of the peripheral wall 7. The housing cover 12 is combined to the housing base 11 to form the box-shaped housing 5.

As shown in FIG. 1, the display unit 3 comprises a display housing 13 and a display device 14 that is accommodated in the display housing 13. The display device 14 comprises a display screen 14a. The display screen 14a is exposed to the outside of the display housing 13 through an opening 13a that is formed in the front surface of the display housing 13.

For example, the display unit 3 is supported to the rear end of the housing 5 by a pair of hinge portions 4a and 4b. The display unit 3 can be moved between a closed position where the display unit is closed from the upper side to cover the upper wall 6 of the housing 5 and an opened position where the display device is raised vertically to the upper wall 6.

Next, the housing 5 of the main unit 2 will be described in detail. The peripheral wall 7 of the housing 5 comprises a front wall 16, a left wall 17, a right wall 18, and a rear wall 19. The front wall 16 is disposed at an end portion (i.e., front end portion) opposite to the end of the housing 5 where the hinge portions 4a and 4b are provided. The front wall 16 extends in the width direction (left-right direction) of the housing 5, and faces a user when the electronic apparatus 1 is used. In the specification, a side close to the user is defined as the front side, a side far from the user is defined as the rear side, and the left and right sides are defined based on the viewing direction of the user.

The rear wall 19 is disposed at the end (rear end) of the housing 5 where the hinge portions 4a and 4b are provided. The rear wall 19 extends substantially in parallel to the front wall 16. The left wall 17 extends in the depth direction (front-rear direction) of the housing 5 so as to connect the left end of the front wall 16 and the left end of the rear wall 19. The right wall 18 extends in the depth direction (front-rear direction) of the housing 5 so as to connect the right end of the front wall 16 and the right end of the rear wall 19.

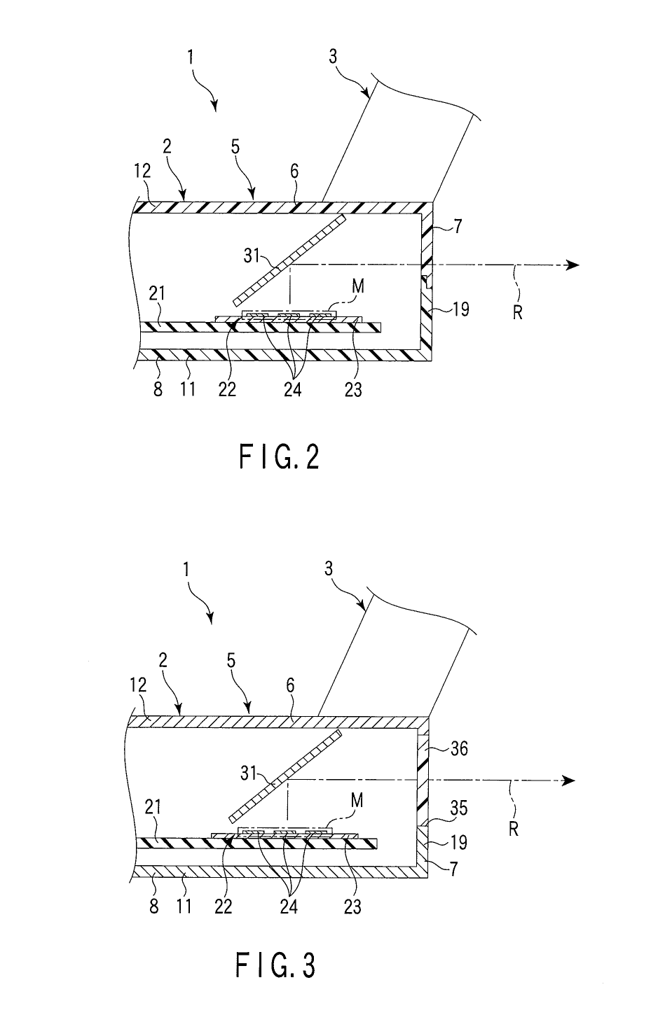

As shown in FIG. 2, a main circuit board 21 is accommodated in the housing 5. The main circuit board 21 is an example of a “circuit board” according to the invention. In the invention, a “circuit board on which an antenna is mounted” may be a circuit board (for example, a circuit board for an antenna) that is different from the main circuit board. For example, the main circuit board 21 according to this embodiment is provided in the housing 5 so as to be substantially horizontal.

An antenna-mounted chip 22 is mounted on the main circuit board 21. The antenna-mounted chip 22 is an example of an “antenna” according to the invention. The antenna-mounted chip 22 comprises an RF chip 23 and plural antenna elements 24 that are provided on the surface of the RF chip 23. For example, the plural antenna elements 24 are arranged in an array.

The antenna-mounted chip 22 uses, for example, a millimeter-wave band or a micro-wave band. Radio waves in the millimeter-wave band or the micro-wave band have characteristics close to light and have relatively high directivity. For example, the antenna-mounted chip 22 has a directivity higher than that of an antenna for a wireless LAN. The antenna-mounted chip 22 radiates a radio wave R in a direction in which the surface having the antenna elements 24 printed thereon faces.

An example of the antenna-mounted chip 22 is an antenna for WirelessHD (trademark). The antenna-mounted chip 22 for WirelessHD can transmit uncompressed HD images using millimeter waves in a 60-GHz band that can ensure a wideband.

As shown in FIG. 2, the antenna-mounted chip 22 is mounted on the main circuit board 21 so as to be substantially horizontal in the housing 5. The antenna-mounted chip 22 radiates the radio wave R in a direction (that is, a substantially vertical direction) orthogonal to the surface of the main circuit board 21. The antenna-mounted chip 22 according to this embodiment radiates the radio wave R to the upper side of the main circuit board 21.

For example, a receiver that receives the radio wave R radiated from the antenna-mounted chip 22 is provided in a display apparatus, such as a television. That is, in many cases, the receiver faces the electronic apparatus 1 (that is, an antenna) in the lateral direction. In the specification, the “lateral direction” means the “peripheral direction of an electronic apparatus”, and comprises the front side, rear side, left side, and right side of the electronic apparatus. In addition, the “lateral direction” is not limited to the horizontal direction, but also comprises an inclined direction with respect to the horizontal direction (for example, a direction that is inclined obliquely upward toward the rear side).

As shown in FIG. 2, the electronic apparatus 1 comprises a reflecting plate 31 that changes the direction of the radio wave R such that the radio wave R radiated from the antenna-mounted chip 22 is reflected to the receiver. The posture of the reflecting plate 31 according to this embodiment is fixed in the housing 5. For example, the reflecting plate 31 is arranged above the antenna-mounted chip 22 and faces the antenna-mounted chip 22. The reflecting plate 31 is inclined obliquely upward toward the rear side with respect to the horizontal direction.

For example, the reflecting plate 31 reflects the radio wave R radiated upward from the antenna-mounted chip 22 to the lateral side of the electronic apparatus 1. That is, the reflecting plate 31 changes the radiation direction of the radio wave R at an angle of about 90 degrees such that the radio wave R radiated upward travels in the horizontal direction. The reflecting plate 31 according to this embodiment reflects the radio wave R to the rear side of the electronic apparatus 1.

In addition, the reflecting plate 31 changes the direction of the radio wave R such that the radio wave R traveling in the horizontal direction is reflected to the antenna-mounted chip 22. The reflecting plate 31 according to this embodiment changes the direction of the radio wave R such that the radio wave R traveling from the rear side is reflected downward. The antenna-mounted chip 22 receives the radio wave R that has been reflected to the antenna-mounted chip 22 by the reflecting plate 31.

An example of the reflecting plate 31 is a metal plate. The reflecting plate 31 is not limited thereto, but any plate may be used as long as it can reflect the radio wave R in the millimeter-wave band or the micro-wave band. For example, the reflecting plate 31 may be a glass plate or a synthetic resin plate having a metal foil formed thereon by a metal plating method or an electrodeposition coating method. As shown in FIG. 2, the area of the reflecting plate 31 is larger than that of an antenna element mounting area M of the antenna-mounted chip 22 in the radiation direction (in this embodiment, the vertical direction) of the radio wave R from the antenna-mounted chip 22. The “antenna element mounting area” means an area of the antenna-mounted chip 22 in which the antenna elements 24 are provided (that is, an area from which the radio wave is radiated).

As shown in FIG. 2, in the housing 5, at least the rear wall 19 is made of a synthetic resin material that can transmit the radio wave R. In the housing 5 according to this embodiment, the housing base 11 and the housing cover 12 are both made of a synthetic resin material. The radio wave R reflected from the reflecting plate 31 passes through the housing 5 and is then emitted to the outside of the housing 5.

The housing 5 (for example, the housing cover 12) has, for example, a holding structure (not shown) that holds the reflecting plate 31. In addition, instead of providing the holding structure in the housing 5, a holding structure provided on the main circuit board 21 may hold the reflecting plate 31.

According to the electronic apparatus 1 having the above-mentioned structure, when a circuit board having an antenna mounted thereon is provided in the housing 5, it is possible to optimize the mounting structure of the housing 5. That is, for example, when an antenna having relatively high directivity, such as WirelessHD, is mounted, the radiation direction of the antenna needs to be oriented to a communication partner (i.e., receiver), and there are various limitations in the mounting position or posture of an antenna or a circuit board having the antenna mounted thereon.

For example, when the antenna-mounted chip 22 is vertically provided in the housing 5 in order to radiate the radio wave R in the lateral direction, the thickness of the housing 5 needs to be equal to or larger than the size of the RF chip 23 (for example, a size of about 3 cm×3 cm). That is, the thickness of the antenna mounting structure is restricted by the size of the RF chip 23. As a result, it is difficult to reduce the thickness of the housing 5.

Therefore, the electronic apparatus 1 according to this embodiment comprises the reflecting plate 31 that reflects the radio wave R in an arbitrary direction using the reflection characteristics of the radio wave R in, for example, the millimeter-wave band or the micro-wave band. When the reflecting plate 31 is provided, restrictions related to directivity are reduced, and it is possible to improve the flexibility of the mounting position or posture of an antenna or a circuit board having the antenna mounted thereon. When the flexibility of the mounting position or posture of an antenna or a circuit board having the antenna mounted thereon is improved, it is possible to achieve a mounting structure suitable to reduce the size or thickness of the housing 5.

When the reflecting plate 31 is provided in the housing 5, it is possible to reduce the overall size of the electronic apparatus 1. When the reflecting plate 31 is fixed in the housing, it is possible to simplify the holding structure of the reflecting plate 31. When the area of the reflecting plate 31 is larger than that of the antenna element mounting area M of the antenna in the radiation direction of the radio wave R from the antenna, it is possible to change the radiation direction of the radio wave R from the antenna with high efficiency.

When the reflecting plate 31 is provided above the antenna and reflects the radio wave R radiated upward from the antenna in the lateral direction, it is possible to arrange the circuit board having the antenna mounted thereon substantially horizontally in the housing 5. For example, an antenna for WirelessHD has a relatively large chip size. Therefore, when a circuit board having the antenna-mounted chip 22 for WirelessHD mounted thereon is arranged substantially horizontally in the housing 5, it is possible to reduce the thickness of the housing 5.

FIG. 3 is a diagram illustrating a modification of the electronic apparatus 1 according to the first embodiment. The housing 5 of the electronic apparatus 1 shown in FIG. 3 is made of a metal material. The rear wall 19 of the housing 5 comprises an opening 35 facing the reflecting plate 31. A cover member 36 made of a synthetic resin material is attached to the opening 35. The radio wave R reflected from the reflecting plate 31 passes through the cover member 36 and is then emitted to the outside of the housing 5. According to this structure, it is also possible to obtain the same effects as those in the first embodiment.

### Second Embodiment

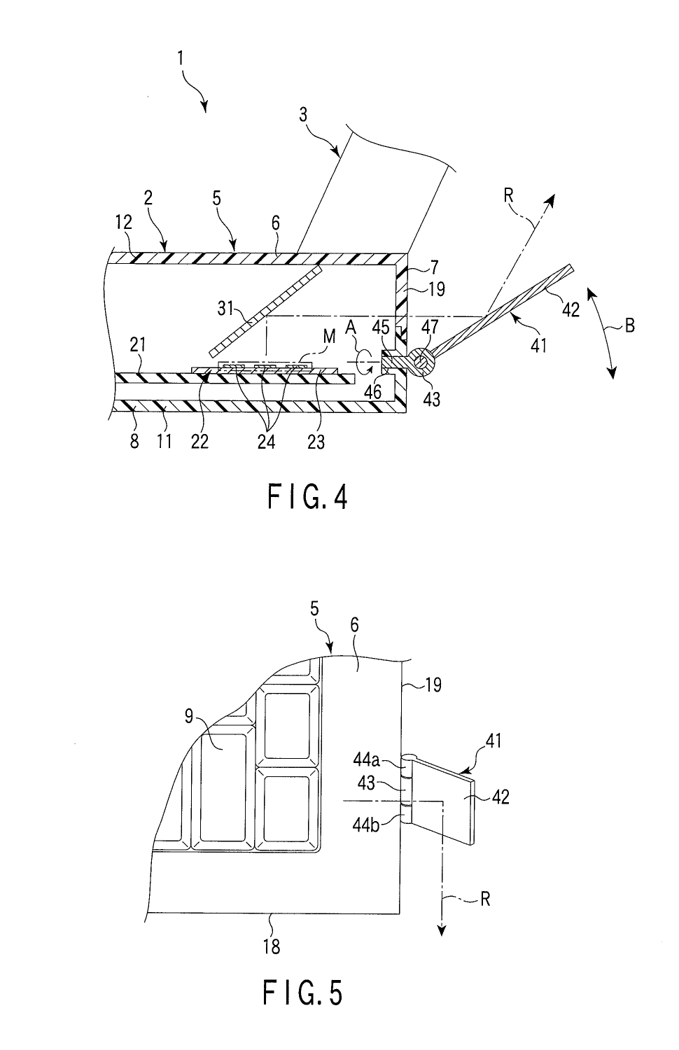

Next, an electronic apparatus 1 according to a second embodiment of the invention will be described with reference to FIGS. 4 to 7. In the second embodiment, components having the same or similar functions as those in the first embodiment are denoted by the same reference numerals, and a detailed description thereof will be omitted. In addition, components other than the components which will be described below are the same as those in the first embodiment.

As shown in FIGS. 4 and 5, the electronic apparatus 1 according to this embodiment comprises a second reflecting plate 41 in addition to the reflecting plate 31 (hereinafter, referred to as a first reflecting plate 31 for discrimination from the second reflecting plate). The second reflecting plate 41 is provided outside the housing 5. The second reflecting plate 41 is detachably attached to the housing 5. The second reflecting plate 41 faces the first reflecting plate 31 and reflects the radio wave R reflected from the first reflecting plate 31 to change the radiation direction of the radio wave R. The second reflecting plate 41 is movable relative to the housing 5. For example, the user can manually adjust the posture of the second reflecting plate 41 in an arbitrary direction or at an arbitrary angle.

When the radio wave R is received, similarly, the radio wave R traveling from the outside of the housing 5 is sequentially reflected from the second reflecting plate 41 and the first reflecting plate 31 and is then received by the antenna-mounted chip 22. The user can manually adjust the posture of the second reflecting plate 41 in an arbitrary direction or at an arbitrary angle to adjust the reception sensitivity of the radio wave.

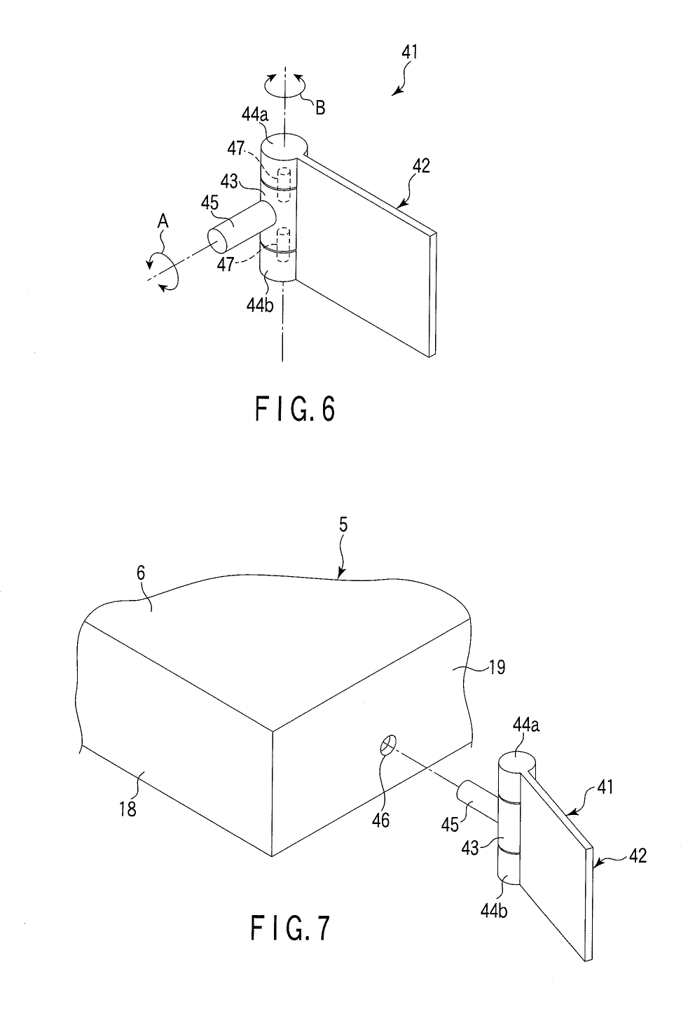

Specifically, as shown in FIG. 6, the second reflecting plate 41 comprises a main body 42, a first hinge portion 43, and a pair of second hinge portions 44a and 44b. The main body 42 is formed in a plate shape, and is made of a material that can reflect the radio wave R. The first hinge portion 43 comprises a first rotating shaft 45. As shown in FIG. 7, the first rotating shaft 45 is fitted into an attachment hole 46 that is provided in the rear wall 19 of the housing 5 and can be rotated with respect to the attachment hole 46. That is, the first rotating shaft 45 can be rotated with respect to the housing 5 (the first rotating shaft 45 can be rotated in the direction of an arrow A in FIG. 6).

The second hinge portions 44a and 44b are connected to the main body 42. The first hinge portion 43 is interposed between the pair of second hinge portions 44a and 44b. Second rotating shafts 47 are provided between the first hinge portion 43 and the second hinge portions 44a and 44b. For example, the second rotating shaft 47 is arranged orthogonal to the first rotating shaft 45 and can be rotated about an axis line that is orthogonal to the axis line of the first rotating shaft 45 (the second rotating shaft 47 can be rotated in the direction of an arrow B in FIG. 6). Since the second reflecting plate 41 comprises the first and second rotating shafts 46 and 47, the second reflecting plate 41 can be inclined in any direction of up, down, right and left. For example, FIG. 4 is a diagram illustrating an example in which the radio wave R is reflected obliquely upward. FIG. 5 is a diagram illustrating an example in which the radio wave R is reflected to the right side.

According to the electronic apparatus 1 having the above-mentioned structure, when a circuit board having an antenna mounted thereon is provided in the housing 5, it is possible to optimize the mounting structure of the housing 5. That is, when the second reflecting plate 41 is provided outside the housing 5, restrictions related to directivity are reduced, and it is possible to improve the flexibility of the mounting position or posture of an antenna or a circuit board having the antenna mounted thereon.

In particular, when the movable second reflecting plate 41 is provided outside the housing 5, it is possible to adjust the second reflecting plate 41 to change the reflection direction of the radio wave R in any direction. Therefore, it is possible to improve the flexibility of the mounting position or posture of an antenna or a circuit board having the antenna mounted thereon.

For example, when an antenna with relatively high directivity is provided in a mobile apparatus, such as a notebook personal computer, and the direction of the antenna is fixed, it is necessary to orient the housing of the mobile apparatus toward the receiver. Therefore, the position or direction where the mobile apparatus is installed is restricted. As a result, the convenience of the mobile apparatus is reduced.

However, as in this embodiment, when the movable second reflecting plate 41 is provided outside the housing 5, it is possible to improve the flexibility of the position or direction where the mobile apparatus is installed and thus improve the convenience of the mobile apparatus.

The second reflecting plate 41 is provided so as to be detachable from the housing 5. When the second reflecting plate 41 is not used, for example, when wireless communication is not performed, the second reflecting plate 42 may be detached. In this way, it is possible to further improve the convenience of a mobile apparatus.

When the second reflecting plate 41 comprises the first rotating shaft 45 that can be rotated with respect to the housing 5 and the second rotating shafts 47 that are provided orthogonal to the first rotating shaft 45, it is possible to incline the second reflecting plate 41 in any direction of up, down, right and left. As a result, restrictions related to directivity are further reduced.

In this case, instead of providing the second reflecting plate 41 outside the housing 5, a circuit board having an antenna mounted thereon may be provided outside the housing 5 and a hinge structure may be provided between the circuit board and the housing. However, in this case, a heat dissipation mechanism needs to be provided on the circuit board, which results in an increase in the size of the circuit board. In addition, a cable for transmitting image data needs to pass through the hinge structure that supports the circuit board, which results in an increase in the size of the hinge structure.

As in this embodiment, when the second reflecting plate 41 is provided outside the housing 5, it is possible to reduce the thickness and size of a structure exposed from the housing 5. In addition, it is also possible to simplify the hinge structure and reduce the size of the hinge structure.

### Third Embodiment

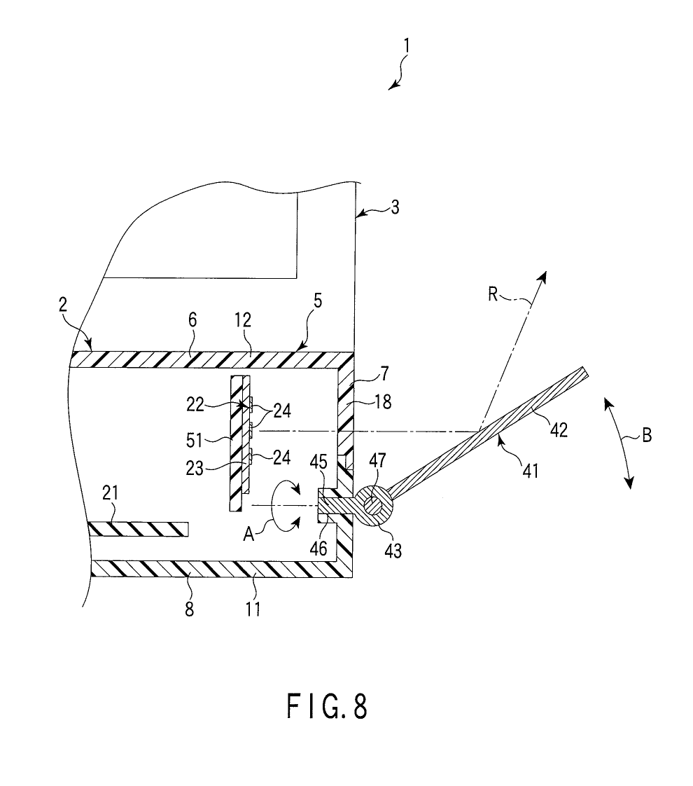

Next, an electronic apparatus 1 according to a third embodiment of the invention will be described with reference to FIG. 8. In the third embodiment, components having the same or similar functions as those in the first and second embodiments are denoted by the same reference numerals, and a detailed description thereof will be omitted. In addition, components other than the components which will be described below are the same as those in the first embodiment.

As shown in FIG. 8, the electronic apparatus 1 according to this embodiment comprises a circuit board 51 having the antenna-mounted chip 22 mounted thereon. The circuit board 51 is provided separately from the main circuit board 21, and is vertically arranged in the housing 5. The circuit board 51 and the antenna-mounted chip 22 according to this embodiment face, for example, the right wall 18 of the housing 5. The antenna-mounted chip 22 radiates the radio wave R in the lateral direction. The circuit board 51 and the antenna-mounted chip 22 may be arranged so as to face the left wall 17, the rear wall 19, or the front wall 16 of the housing 5.

An example of the reflecting plate 41 according to this embodiment is the same as the second reflecting plate 41 according to the second embodiment. That is, the reflecting plate 41 is provided outside the housing 5 so as to be detachable from the housing 5. The reflecting plate 41 can be moved relative to the housing 5. For example, a user can manually adjust the posture of the reflecting plate 41 in an arbitrary direction or at an arbitrary angle. The reflecting plate 41 comprises the first and second rotating shafts 46 and 47 such that it can be inclined in any direction of up, down, right and left. The reflecting plate 41 reflects the radio wave R that has been radiated from the antenna-mounted chip 22 in the lateral direction to the receiver in an arbitrary direction.

According to the electronic apparatus 1 having the above-mentioned structure, when a circuit board having an antenna mounted thereon is provided in the housing 5, it is possible to optimize the mounting structure of the housing 5. That is, when the reflecting plate 41 is provided outside the housing 5, restrictions related to directivity are reduced, and it is possible to improve the flexibility of the mounting position or posture of an antenna or a circuit board having the antenna mounted thereon.

In particular, when the movable reflecting plate 41 is provided outside the housing 5, it is possible to adjust the reflecting plate 41 to change the reflection direction of the radio wave R in any direction. Therefore, it is possible to improve the flexibility of the mounting position or posture of an antenna or a circuit board having the antenna mounted thereon.

Although the electronic apparatuses 1 according to the first to third embodiments of the invention have been described above, the invention is not limited thereto. The components according to the first to third embodiments may be appropriately combined with each other. In addition, the invention is not limited to the above-described embodiments, but various modifications and changes of the components can be made without departing from the scope and spirit of the invention at the implementation stage.

For example, in the first and second embodiments, the reflecting plate 31 reflects the radio wave R to the rear side of the electronic apparatus 1, but the invention is not limited thereto. The reflecting plate 31 may reflect the radio wave R to the front side, the left side, or the right side of the electronic apparatus 1. The invention is not limited to the structure in which the reflecting plate 31 reflects the radio wave R in the horizontal direction, but the reflecting plate 31 may reflect the radio wave R in a direction that is inclined with respect to the horizontal direction (for example, in a direction that is inclined obliquely upward toward the rear side).

In addition, the antenna may be mounted on the lower surface of the circuit board and radiate a radio wave downward, and the reflecting plate 31 may be provided below the circuit board and reflect the radio wave radiated downward from the antenna in the lateral direction of the electronic apparatus 1.

In the second embodiment, the second reflecting plate 41 is attached to the rear wall 19 of the housing 5, but the invention is not limited thereto. For example, the second reflecting plate 41 may be attached to the front wall 16, the left wall 17, or the right wall 18. In the third embodiment, the reflecting plate 41 is attached to the right wall 18 of the housing 5, but the invention is not limited thereto. For example, the reflecting plate 41 may be attached to the front wall 16, the left wall 17, or the rear wall 19. The reflecting plate 41 (second reflecting plate 41) may be attached at any position outside the housing 5.

The reflecting plate 41 (second reflecting plate 41) may comprise only one of the first and second rotating shafts 46 and 47 and may be rotated about one axis. The reflecting plate 41 may not be detachable from the housing 5 but fixed to the housing 5. The reflecting plate 31 (first reflecting plate 31) may be movably provided in the housing 5.

In the second and third embodiments, the housing 5 may be made of a metal material, the opening 35 may be provided in a portion of the housing 5 through which the radio wave passes, and the cover member 36 made of a synthetic resin material may be attached to the opening 35.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a main unit comprising a housing comprising an upper wall, a rear wall extending downward from an end portion of the upper wall and a front wall opposite to the rear wall, the main unit being configured to be placed on a desk with the rear wall facing a communicating party for use;
a display unit comprising a display screen and rotatably attached to the main unit, the display unit being configured to be rotated between a closed position where the display screen is covered by the upper wall and an opened position where the display screen is exposed;
a circuit board in the housing of the main unit and substantially parallel to the upper wall;
a directional antenna on the circuit board and substantially parallel to the upper wall, the antenna being configured to emit a radio wave in a direction substantially orthogonal to the upper wall; and
a reflecting plate between the antenna and an inner surface of the housing, the reflecting plate being configured to reflect the radio wave from the antenna toward the rear wall in order to allow the radio wave to travel toward the communicating party through the rear wall,
wherein the electronic apparatus is configured to be operated with the display screen and the communicating party being in a same direction from a perspective of a position facing the front wall.

2. The electronic apparatus of claim 1, wherein the communicating party is a display device configured to display a content sent by the radio wave.

3. The electronic apparatus of claim 1, wherein the antenna is configured to use a millimeter wave or a microwave.

4. The electronic apparatus of claim 1, wherein the antenna comprises an RF chip and arrayed antenna elements on a surface of the RF chip.
